(19) United States
(12) Patent Application Publication
(10) Pub. No.: US 2011/0273175 A1
(43) Pub. Date: Nov. 10, 2011

(54) PERMANENT MAGNETIC ASSEMBLY FOR

(75) Inventors: Holger Timinger, Hamburg (DE); Jurgen Weizenecker, Stutensee (DE); Bernhard Gleich, Hamburg (DE)

(73) Assignee: KONINKLIJKE PHILIPS ELECTRONICS N.V., EINDHOVEN (NL)

(21) Appl. No.: 13/139,372

(22) PCT Filed: Dec. 14, 2009
(86) PCT No.: PCT/IB09/55741

§ 371 Date: Jul. 26, 2011

(30) Foreign Application Priority Data
Dec. 17, 2008 (EP) 08172014.6

(51) Int. Cl. G01R 33/24; G01R 33/383

(52) U.S. Cl. 324/301; 324/318

(57) ABSTRACT

The present invention relates to an arrangement (10) for influencing and/or detecting magnetic particles in a region of action (300). The arrangement (10) comprises selection means (210) for generating a magnetic selection field (211) having a pattern in space of its magnetic field strength such that a first sub-zone (301) having a low magnetic field strength and a second sub zone (302) having a higher magnetic field strength are formed in the region of action (300), drive means (220) for changing the position in space of the two sub-zones (301, 302) in the region of action (300) by means of a magnetic drive field (221) so that the magnetization of the magnetic material changes locally, and receiving means (230) for acquiring detection signals, which detection signals depend on the magnetization in the region of action (300), which magnetization is influenced by the change in the position in space of the first and second sub-zone (301, 302). The selection means (210) comprises a permanent magnetic assembly having at least one permanent magnetic unit (213) comprising a plurality of magnetic sub-elements (214) wherein the magnetic sub-elements (214) have individually fixed magnetization orientation, and are bonded together to form said at least one permanent magnetic unit (213).

### FIELD OF THE INVENTION

The present invention relates to an arrangement for influencing and/or detecting magnetic particles in a region of action. The present invention further relates a permanent magnetic assembly, in particular for use in an arrangement for influencing and/or detecting magnetic particles in a region of action.

### BACKGROUND OF THE INVENTION

An arrangement of this kind is known from German patent application DE 101 51 778 A1. In the arrangement described in that publication, first of all a magnetic selection field having a spatial distribution of the magnetic field strength is generated by magnetic selection means such that a first sub-zone, which is also called magnetic field-free point, having a relatively low magnetic field strength and a second sub-zone having a relatively high magnetic field strength are formed in the examination zone. The position in space of the sub-zones in the examination zone is then shifted, so that the magnetization of the particles in the examination zone changes locally. Signals are recorded which are dependent on the magnetization in the examination zone, which magnetization has been influenced by the shift in the position in space of the sub-zones, and information concerning the spatial distribution of the magnetic particles in the examination zone is extracted from these signals, so that an image of the examination zone can be formed. Such an arrangement has the advantage that it can be used to examine arbitrary examination objects—e.g. human bodies—in a non-destructive manner and without causing any damage and with a high spatial resolution, both close to the surface and remote from the surface of the examination object.

A similar arrangement and method is known from Gleich, B. and Weizenecker, J. (2005), “Tomographic imaging using the nonlinear response of magnetic particles” in nature, vol. 435, pp. 1214-1217. The arrangement and method for magnetic particle imaging (MPI) described in that publication takes advantage of the non-linear magnetization curve of small magnetic particles.

Known arrangements of this type usually comprise permanent magnets or coils as magnetic selection means. If permanent magnets are used, the selection field, which comprises the two sub-zones as mentioned above, is produced by two permanent magnets which are aligned along the same axis, wherein the two magnets are facing each other with the same poles, both with the north pole or both with the south pole. Such an arrangement has shown the disadvantage that the efficiency of the magnetic selection means is rather low so that the permanent magnets need to be sized in a very large scale in order to produce the desired high magnetic gradient of the selection field. This is in particular disadvantageous since it is preferable to design the components as small and efficient as possible in order to realize the housing of the MPI arrangement as tight as possible. Nevertheless, known permanent magnets, in particular for use in magnetic selection means, have so far not shown satisfactory efficiency.

### SUMMARY OF THE INVENTION

It is therefore an object of the present invention to provide an arrangement of the kind mentioned initially and a permanent magnetic assembly in particular for use in such an arrangement, wherein the efficiency of the magnetic selection means, meaning the strength of the gradient field per magnetic volume unit, is significantly increased.

The object is achieved according to the present invention by an arrangement for influencing and/or detecting magnetic particles in a region of action, comprising:
selection means for generating a magnetic selection field having a pattern in space of its magnetic field strength such that a first sub-zone having a low magnetic field strength and a second sub-zone having a higher magnetic field strength are formed in the region of action,
drive means for changing the position in space of the two sub-zones in the region of action by means of a magnetic drive field so that the magnetization of the magnetic material changes locally, and
receiving means for acquiring detection signals, which detection signals depend on the magnetization in the region of action, which magnetization is influenced by the change in the position in space of the first and second sub-zone, wherein:
the selection means comprises a permanent magnetic assembly having at least one permanent magnetic unit comprising a plurality of magnetic sub-elements,
the magnetic sub-elements have individually fixed magnetization orientations, and
the magnetic sub-elements are bonded together to form said at least one permanent magnetic unit.

The object is furthermore achieved by a permanent magnetic assembly, in particular for use in an arrangement as claimed in claim 1, wherein:
the permanent magnetic assembly comprises at least one permanent magnetic unit comprising a plurality of magnetic sub-elements,
the magnetic sub-elements have individually fixed magnetization orientations, and
the magnetic sub-elements are bonded together to form said at least one permanent magnetic unit.

According to the present invention, it is to be understood that the drive means and/or the receiving means can at least partially be provided in the form of one single coil or solenoid. However, it is preferred according to the present invention that separate coils are provided to form the drive means and the receiving means. Furthermore according to the present invention, the drive means and/or the receiving means can each be composed of separate individual parts, especially separate individual coils or solenoids, provided and/or arranged such that the separate parts form together the drive means and/or the receiving means. Especially for the drive means, a plurality of parts, especially pairs for coils (e.g. in a Helmholtz or Anti-Helmholtz configuration) are preferred in order to provide the possibility to generate and/or to detect components of magnetic fields directed in different spatial directions.

By dividing the at least one permanent magnetic unit of the selection means into a plurality of small magnetic sub-elements, it is possible to produce a very strong magnetic gradient field. Since the magnetization orientation of each sub-element can be individually influenced, the strength of the gradient field per magnetic volume unit can be significantly increased. The various sub-elements are thereby arranged in such a manner that the magnetic gradient field generated by each sub-element can contribute to the overall magnetic gradient field. The magnetic orientation of each sub-element can therefore be discretized in order to calculate the contribution of each sub-element to the total magnetic gradient field in different possible configurations. The specific configuration can be arbitrarily changed depending on the requirements of the desired application. Overall, this allows a stronger, better controllable and individually adaptable design in contrast to a uniformly magnetized permanent magnet. Additionally, the overall volume of the selection means can also be significantly reduced.

According to an embodiment of the present invention, it is preferred that the magnetization orientation of adjacent magnetic sub-elements is different and resembles the desired magnetic flux lines for optimally contributing to the total magnetic field. Instead of having a uniformly magnetized permanent magnet, said at least one permanent magnetic unit of the selection means, according to the present invention, comprises a plurality of magnetic sub-elements, wherein the optimal magnetization orientation is calculated for each position in space. By resembling the desired magnetic flux lines the magnetization orientation of each sub-element optimally contributes to the total magnetic field. This can be easily defined by calculating the fraction of contribution to the total magnetic selection field for each sub-element separately. This calculation shows that the highest gradient can be reached if, independent of the shape of the permanent magnetic unit, the desired shape of the magnetic flux lines is resembled by the magnetization orientation of the sub-elements. This leads to an increase of the gradient of the magnetic field of approximately 20 to 30% in comparison to a uniformly magnetized permanent magnet, i.e. the same magnetic gradient field can be generated by an approximately 20 to 30% smaller magnetic volume.

According to an embodiment of the present invention, it is furthermore preferred that the magnetization orientation of said magnetic sub-elements is limited to the following euler angles: θ=φ=0; θ=π/4 and φ=0; θ=φ=π/4. The limitation of the magnetization orientation to the above-mentioned euler angles has the advantage that the production variance is limited to a specific number of different sub-elements, respectively magnetization orientations, i.e. the production complexity is reduced and production costs can be saved. Even though the production is in this embodiment limited to only three different types of magnetic sub-elements, 26 different magnetic orientations can be realized depending on how they are arranged in the magnetic assembly. The magnetic sub-elements with the magnetization orientation θ=φ=0 can be arranged in all three spatial directions and their opposite directions, i.e. six magnetization orientation can be realized. In a similar way the magnetic sub-elements with the magnetization orientation θ=π/4 and φ=0 can be arranged in twelve different ways, i.e. the magnetization orientation can be directed towards all edges of the cube. Furthermore, the magnetic sub-elements with the magnetization orientation θ=φ=π/4 can be arranged in eight different ways, i.e. the magnetization orientation can be directed towards all corners of the cube. This results in the above mentioned 26 different orientations which is realized with only three different kinds of magnetic sub-elements. The number of orientations is therefore still sufficient so that the above mentioned increase of the gradient of the magnetic field of approximately 20 to 30% in comparison to a uniformly magnetized permanent magnet can still be maintained.

It is furthermore preferred according to the present invention that the magnetic sub-elements are formed and bonded together to form said at least one permanent magnetic unit in the shape of a ring, a torus or a disc. The advantage of forming the permanent magnetic unit as a ring or a torus is that such a “donut”-like shape allows to generate a mainly linear magnetic gradient within the inner hole of the ring respectively the torus. The inner hole of the ring or the torus is at the same time optimally suitable as patient bore, in particular in case of human or animal patients. Furthermore, such a shape is space-saving and therefore allows to save magnetic material by still maintaining a strong magnetic gradient field. In an application of the present invention it is sometimes meaningful to introduce two permanent magnetic units in the shape of a torus. If on the other hand only one permanent magnetic unit is used as magnetic selection means, the shape of the permanent magnetic assembly might be rather complex in order to realize the desired magnetic selection field. It is furthermore possible to form said at least one of permanent magnetic units as a disc. This is an even more space-saving shape. On the other hand, the gradient in such an embodiment is rather bent.

According to a further embodiment of the present invention, it is preferred that the magnetic sub-elements are in the shape of cubes. Magnetized cubes are easy to manufacture and the advantage of the cube shape is that the sub-elements can be easily assembled together to form an arbitrary shape of said permanent magnetic units. Furthermore, due to the relatively large and flat surfaces of a cube, the fixing between the magnetic sub-elements is facilitated.

In a further preferred embodiment of the present invention, the magnetic sub-elements are bonded together by glue or screws and/or are cast. In order to overcome the very strong magnetic forces between different sub-elements, a reliable fixation, in particular by glue or screws, is necessary. In conjunction with the cube shape of the sub-elements, each sub-element can be glued, screwed or cast together with each of its six adjacent other sub-elements at each of the six sides of the cube. It is in particular advantageous, to glue or cast the magnetic sub-elements together since, in contrast to screwing, no holes or threats have to be provided for the magnetic sub-elements. It has to be noted that any other suitable method which can withstand the magnetic forces in the assembly is also conceivable.

It is furthermore preferred according to an embodiment of the present invention that the magnetic sub-elements are coated with a non-conducting layer, in particular epoxy. By such a coating with a non-conducting epoxy layer, eddy-currents, which might be induced by the drive field of the MPI scanner, can be reduced significantly. This is an important effect since the perturbation due to occurring eddy-currents is thereby at least partly suppressed. Especially the resulting loss, which is caused by the eddy currents, can otherwise destroy the magnetization, if the temperature increases beyond the critical temperature of the magnetic material. Therefore, coated sub-volumes allow the generation of a more stable and controllable magnetic selection field.

### BRIEF DESCRIPTION OF THE DRAWINGS

These and other aspects of the invention will be apparent from and elucidated with reference to the embodiment(s) described hereinafter. In the following drawings:

FIG. 1 shows a schematic view of a magnetic particle imaging (MPI) arrangement in principle,

FIG. 2 shows a schematic view of the physical principle of the selection means according to the prior art,

FIG. 3 shows an enlarged view of a magnetic particle present in the region of action,

FIGS. 4a and 4b show the magnetization characteristics of such particles,

FIG. 5 shows a perspective view of the selection means according to an embodiment of the present invention,

FIG. 6 shows the magnetization orientation of the magnetic sub-elements in a cross-section of the selection means according to an embodiment of the present invention,

FIG. 7 shows a schematic view of the selection means according to an embodiment of the present invention including the magnetic flux lines of the magnetic selection field, and

FIG. 8 shows a schematic view of the selection means comprising uniformly magnetized permanent magnets according to the prior art.

### DETAILED DESCRIPTION OF THE INVENTION

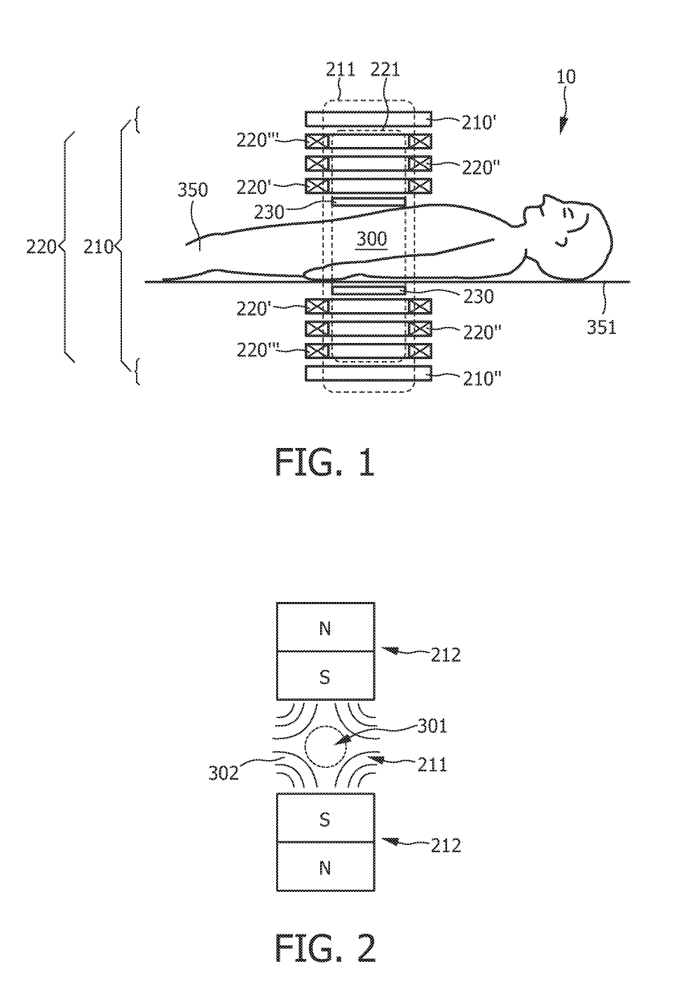

FIG. 1 shows an arbitrary object to be examined by means of a MPI arrangement 10. The reference numeral 350 in FIG. 1 denotes an object, in this case a human or animal patient, who is arranged on a patient table 351, only part of the top of which is shown. Prior to the application of the method according to the present invention, magnetic particles 100 (not shown in FIG. 1) are arranged in a region of action 300 of the inventive arrangement 10. Especially prior to a therapeutical and/or diagnostical treatment of, for example, a tumor, the magnetic particles 100 are positioned in the region of action 300, e.g. by means of a liquid (not shown) comprising the magnetic particles 100 which is injected into the body of the patient 350.

FIG. 2 shows the physical principal of generating the magnetic selection field 211 according to the prior art with two permanent magnets 212. The two permanent magnets 212 together form a selection means 210 whose range defines the region of action 300 which is also called the region of treatment 300. The two permanent magnets 212 are in this embodiment arranged above and below the patient 350 or above and below the table top, and thereby extend along one axis, with both south poles facing each other. It has to be noted, that the two permanent magnets 212 can be of course also arranged in the same way with both north poles facing each other, i.e. it does not matter which of the poles oppose each other as long as the opposing poles have the same polarity.

In the space between the two, respectively 6 poles of said permanent magnets 212, a magnetic field 211 is formed. The magnetic field 211 which is generated by the selection means 210 is a static gradient field, represented by the field lines shown in FIG. 2. The magnetic selection field 211 has a substantially constant gradient in the direction of the (e.g. vertical) axis of the permanent magnets 212 of the selection means 210 and reaches the value zero in the centric point of the field 211. Starting from this field-free point (not individually shown in FIG. 2), the field strength of the magnetic selection field 211 increases in all three spatial directions as the distance increases from the field-free point. In a first sub-zone 301 or region 301 which is denoted by a dashed line around the field-free point the field strength is so small that the magnetization of particles 100 present in that first sub-zone 301 is not saturated, whereas the magnetization of particles 100 present in a second sub-zone 302 (outside the region 301) is in a state of saturation. The field-free point or first sub-zone 301 of the region of action 300 is preferably a spatially coherent area; it may also be a punctiform area or else a line or a flat area. In the second sub-zone 302 (i.e. in the residual part of the region of action 300 outside of the first sub-zone 301) the magnetic field strength is sufficiently strong to keep the particles 100 in a state of saturation. By changing the position of the two sub-zones 301, 302 within the region of action 300, the (overall) magnetization in the region of action 300 changes. By measuring the magnetization in the region of action 300 or a physical parameters influenced by the magnetization, information about the spatial distribution of the magnetic particles in the region of action can be obtained. In order to change the relative spatial position of the two sub-zones 301, 302 in the region of action 300, a further magnetic field, the so-called magnetic drive field 221, is superposed to the selection field 211 in the region of action 300 or at least in a part of the region of action 300.

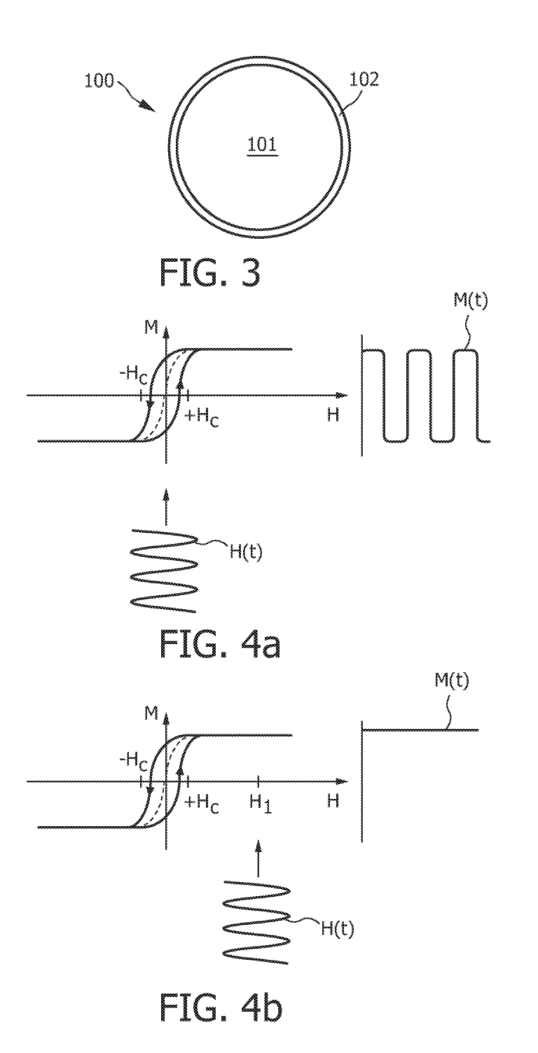

FIG. 3 shows an example of a magnetic particle 100 of the kind used together with an arrangement 10 of the present invention. It comprises for example a spherical substrate 101, for example, of glass which is provided with a soft-magnetic layer 102 which has a thickness of, for example, 5 nm and consists, for example, of an iron-nickel alloy (for example, Permalloy). This layer may be covered, for example, by means of a coating layer 103 which protects the particle 100 against chemically and/or physically aggressive environments, e.g. acids. The magnetic field strength of the magnetic selection field 211 required for the saturation of the magnetization of such particles 100 is dependent on various parameters, e.g. the diameter of the particles 100, the used magnetic material for the magnetic layer 102 and other parameters.

In the case of e.g. a diameter of 10 μm, a magnetic field of approximately 800 A/m (corresponding approximately to a flux density of 1 mT) is then required, whereas in the case of a diameter of 100 μm a magnetic field of 80 A/m suffices. Even smaller values are obtained when a coating 102 of a material having a lower saturation magnetization is chosen or when the thickness of the layer 102 is reduced.

For further details of the preferred magnetic particles 100, the corresponding parts of DE 10151778 are hereby incorporated by reference, especially paragraphs 16 to 20 and paragraphs 57 to 61 of EP 1304542 A2 claiming the priority of DE 10151778.

The size of the first sub-zone 301 is dependent on the one hand on the strength of the gradient of the magnetic selection field 211 and on the other hand on the field strength of the magnetic field required for saturation. For a sufficient saturation of the magnetic particles 100 at a magnetic field strength of 80 A/m and a gradient (in a given space direction) of the field strength of the magnetic selection field 211 amounting to 160 10³ A/m2, the first sub-zone 301 in which the magnetization of the particles 100 is not saturated has dimensions of about 1 mm (in the given space direction).

When a further magnetic field—in the following called a magnetic drive field 221 is superposed on the magnetic selection field 211 (or gradient magnetic field 211) in the region of action 300, the first sub-zone 301 is shifted relative to the second sub-zone 302 in the direction of this magnetic drive field 221; the extent of this shift increases as the strength of the magnetic drive field 221 increases. When the superposed magnetic drive field 221 is variable in time, the position of the first sub-zone 301 varies accordingly in time and in space. It is advantageous to receive or to detect signals from the magnetic particles 100 located in the first sub-zone 301 in another frequency band (shifted to higher frequencies) than the frequency band of the magnetic drive field 221 variations. This is possible because frequency components of higher harmonics of the magnetic drive field 221 frequency occur due to a change in magnetization of the magnetic particles 100 in the region of action 300 as a result of the non-linearity of the magnetization characteristics.

In order to generate these magnetic drive fields 221 for any given direction in space, three further coil pairs are provided, namely a second coil pair 220′, a third coil pair 220″ and a fourth coil pair 220′″ which together are called drive means 220 in the following. For example, the second coil pair 220′ generates a component of the magnetic drive field 221 which extends in the direction of the coil axis of the first coil pair 210′, 210″ or the selection means 210, i.e. for example vertically. To this end the windings of the second coil pair 220′ are traversed by equal currents in the same direction. The effect that can be achieved by means of the second coil pair 220′ can in principle also be achieved by the superposition of currents in the same direction on the opposed, equal currents in the first coil pair 210′, 210″, so that the current decreases in one coil and increases in the other coil. However, and especially for the purpose of a signal interpretation with a higher signal to noise ratio, it may be advantageous when the temporally constant (or quasi constant) selection field 211 (also called gradient magnetic field) and the temporally variable vertical magnetic drive field are generated by separate coil pairs of the selection means 210 and of the drive means 220.

The two further coil pairs 220″, 220′″ are provided in order to generate components of the magnetic drive field 221 which extend in a different direction in space, e.g. horizontally in the longitudinal direction of the region of action 300 (or the patient 350) and in a direction perpendicular thereto. If third and fourth coil pairs 220″, 220′″ of the Helmholtz type were used for this purpose, these coil pairs would have to be arranged to the left and the right of the region of treatment or in front of and behind this region, respectively. This would affect the accessibility of the region of action 300 or the region of treatment 300. Therefore, the third and/or fourth magnetic coil pairs or coils 220″, 220′″ are also arranged above and below the region of action 300 and, therefore, their winding configuration must be different from that of the second coil pair 220′. Coils of this kind, however, are known from the field of magnetic resonance apparatus with open magnets (open MRI) in which a radio frequency (RF) coil pair is situated above and below the region of treatment, said RF coil pair being capable of generating a horizontal, temporally variable magnetic field. Therefore, the construction of such coils need not be further elaborated herein.

The arrangement 10 according to the present invention further comprise receiving means 230 that are only schematically shown in FIG. 1. The receiving means 230 usually comprise coils that are able to detect the signals induced by magnetization pattern of the magnetic particles 100 in the region of action 300. Coils of this kind, however, are known from the field of magnetic resonance apparatus in which e.g. a radio frequency (RF) coil pair is situated around the region of action 300 in order to have a signal to noise ratio as high as possible. Therefore, the construction of such coils need not be further elaborated herein.

The frequency ranges usually used for or in the different components of the selection means 210, drive means 220 and receiving means 230 are roughly as follows: The magnetic field generated by the selection means 210 does either not vary at all over the time or the variation is comparably slow, preferably between approximately 1 Hz and approximately 100 Hz. The magnetic field generated by the drive means 220 varies preferably between approximately 25 kHz and approximately 100 kHz. The magnetic field variations that the receiving means are supposed to be sensitive are preferably in a frequency range of approximately 50 kHz to approximately 10 MHz.

FIGS. 4a and 4b show the magnetization characteristic, that is, the variation of the magnetization M of a particle 100 (not shown in FIGS. 4a and 4b) as a function of the field strength H at the location of that particle 100, in a dispersion with such particles. It appears that the magnetization M no longer changes beyond a field strength +H_{c} and below a field strength −H_{c}, which means that a saturated magnetization is reached. The magnetization M is not saturated between the values +H_{c} and −H_{c}.

FIG. 4a illustrates the effect of a sinusoidal magnetic field H(t) at the location of the particle 100 where the absolute values of the resulting sinusoidal magnetic field H(t) (i.e. “seen by the particle 100”) are lower than the magnetic field strength required to magnetically saturate the particle 100, i.e. in the case where no further magnetic field is active. The magnetization of the particle 100 or particles 100 for this condition reciprocates between its saturation values at the rhythm of the frequency of the magnetic field H(t). The resultant variation in time of the magnetization is denoted by the reference M(t) on the right hand side of FIG. 4a. It appears that the magnetization also changes periodically and that the magnetization of such a particle is periodically reversed.

The dashed part of the line at the centre of the curve denotes the approximate mean variation of the magnetization M(t) as a function of the field strength of the sinusoidal magnetic field H(t). As a deviation from this centre line, the magnetization extends slightly to the right when the magnetic field H increases from −H_{c} to +H_{c} and slightly to the left when the magnetic field H decreases from +H_{c} to −H_{c}. This known effect is called a hysteresis effect which underlies a mechanism for the generation of heat. The hysteresis surface area which is formed between the paths of the curve and whose shape and size are dependent on the material, is a measure for the generation of heat upon variation of the magnetization.

FIG. 4b shows the effect of a sinusoidal magnetic field H(t) on which a static magnetic field H₁ is superposed. Because the magnetization is in the saturated state, it is practically not influenced by the sinusoidal magnetic field H(t). The magnetization M(t) remains constant in time at this area. Consequently, the magnetic field H(t) does not cause a change of the state of the magnetization.

FIG. 5 shows the selection means 210 according to an embodiment of the present invention which are realized by a permanent magnetic assembly having two permanent magnetic units 213. These permanent magnetic units 213 are assembled together of a plurality of cubic magnetic sub-elements 214 which together, in this embodiment, form the shape of a torus with a centric hole 215, respectively a “donut”-like shape. It has to be noted that the magnetic sub-elements 214 can be also assembled together in any arbitrary form, e.g. a disc or a ring. In case of a torus, the magnetic gradient of the selection field 211 is mainly linear within the inner hole 215 of the permanent magnetic unit (torus) 213 and has, similar to the arrangement shown in FIG. 2, a substantially constant gradient in the direction of the axis of the permanent magnetic units 213. The gradient reaches the value zero in the centric point between the two permanent magnetic units 213. Starting from this field-free point, the field strength of the magnetic selection field 211 increases in all three spatial directions as the distance increases from the field-free point.

In an application of the present invention, the two permanent magnetic units 213 can be either arranged above and below the patient or the hole 215 can serve as a patient bore.

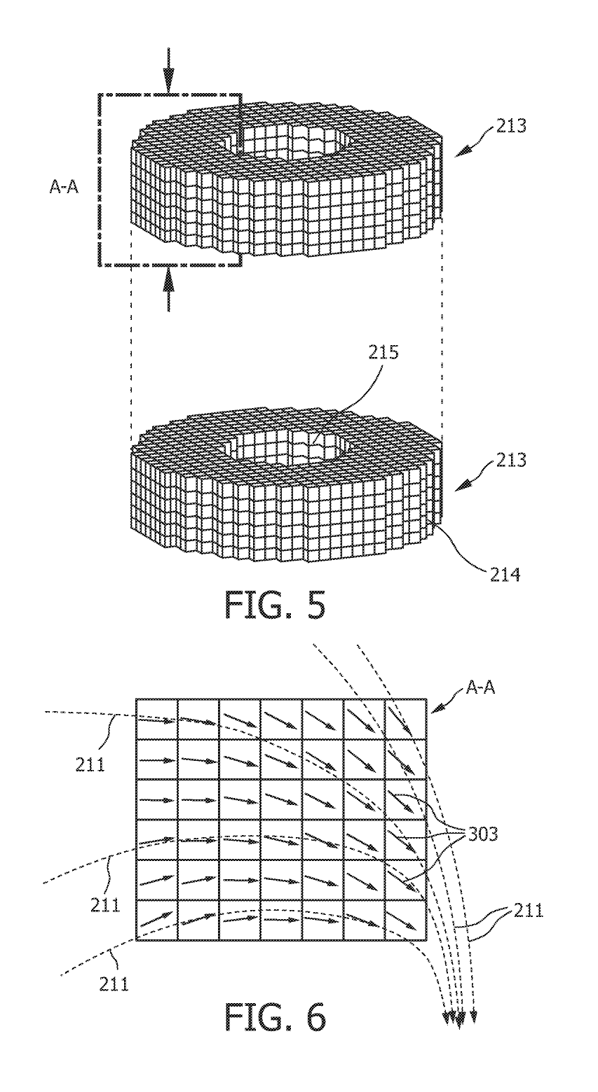

Due to magnetic forces between the magnetic sub-elements 214, it is necessary to provide a reliable fixation of the assembly. This is preferably realized by either a special glue technique, by screws or by casting the sub-elements together. Each magnetic sub-element 214 is arranged such that the magnetic fraction field of each sub-element 214 contributes to the overall magnetic selection field 211. The magnetization orientation of the sub-elements 214 is thereby individually fixed so that the magnetization orientation of adjacent sub-elements 214 can differ, as it can be seen from FIG. 6. This allows the production of a very strong field compared to the magnetic field production with two uniformly magnetized permanent magnets as shown in FIG. 2. However, the difference in magnetization orientation of adjacent sub-elements 214 cannot be too large since this would too strongly increase the magnetic forces and therefore complicate the technical feasibility. Nevertheless, the optimal contribution of each sub-element is reached if the magnetization orientation of the sub-elements resemble the desired magnetic flux lines. This leads to an increase of the gradient of the magnetic field of approximately 20 to 30% in comparison to a uniformly magnetized permanent magnet, i.e. the same magnetic gradient field can be generated by a 20 to 30% smaller magnetic volume.

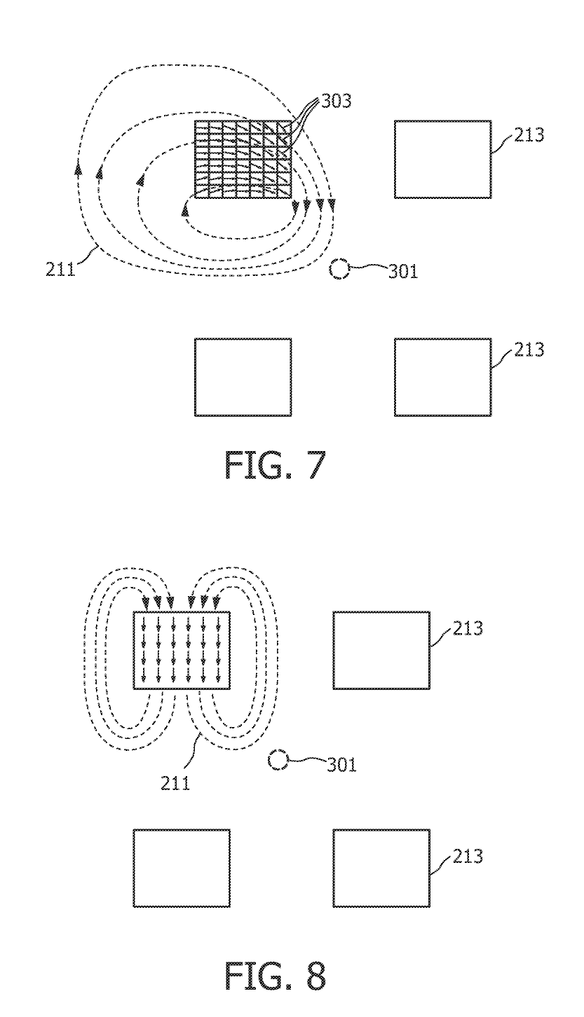

The impact of the above described individual magnetization of the permanent magnets, in contrast to a uniformly magnetized permanent magnet, can be additionally seen by comparing FIG. 7 and FIG. 8. As can be seen, the magnetic flux lines of the magnetic selection field 211 in FIG. 7, where the permanent magnetic assembly comprises sub-elements 303 with individually fixed magnetization orientations, are compressed towards the inner part of the assembly, respectively towards the field-free point. The magnetic selection field is therefore, in contrast to FIG. 8, asymmetric. As has been already explained above, the gradient and the magnetic field strength of such a field is therefore significantly increased. The flux lines in FIG. 7 therefore resemble the desired selection field 211 in a very good way, whereas the magnetic field produced by a uniformly magnetized permanent magnet as in FIG. 8 is neither strong enough nor of the desired shape.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measures cannot be used to advantage.

Any reference signs in the claims should not be construed as limiting the scope.

1. An arrangement (10) for influencing and/or detecting magnetic particles in a region of action (300), comprising:
selection means (210) for generating a magnetic selection field (211) having a pattern in space of its magnetic field strength such that a first sub-zone (301) having a low magnetic field strength and a second sub-zone (302) having a higher magnetic field strength are formed in the region of action (300),
drive means (220) for changing the position in space of the two sub-zones (301, 302) in the region of action (300) by means of a magnetic drive field (221) so that the magnetization of the magnetic material changes locally, and
receiving means (230) for acquiring detection signals, which detection signals depend on the magnetization in the region of action (300), which magnetization is influenced by the change in the position in space of the first and second sub-zone (301, 302), wherein:
the selection means (210) comprises a permanent magnetic assembly having at least one permanent magnetic unit (213) comprising a plurality of magnetic sub-elements (214),
the magnetic sub-elements (214) have individually fixed magnetization orientations, and
the magnetic sub-elements (214) are bonded together to form said at least one permanent magnetic unit (213).

2. An arrangement according to claim 1, characterized in that the magnetization orientation of adjacent magnetic sub-elements (214) is different and resembles the desired magnetic flux lines for optimally contributing to the total magnetic field (211).

3. An arrangement according to claim 1, characterized in that the magnetization orientation of said magnetic sub-elements (214) is limited to the following Euler angles: θ=φ=0; θ=π/4 and φ=0; θ=φ=π/4.

4. An arrangement according to claim 1, characterized in that the magnetic sub-elements (214) are formed and bonded together to form said at least one permanent magnetic unit (213) in the shape of a ring, a torus or a disk.

5. An arrangement according to claim 1, characterized in that the magnetic sub-elements (214) are in the shape of cubes.

6. An arrangement according to claim 1, characterized in that the magnetic sub-elements (214) are bonded together by glue or screws and/or are cast.

7. An arrangement according to claim 1, characterized in that the magnetic sub-elements (214) are coated with a non-conducting layer, in particular epoxy.

8. A permanent magnetic assembly, in particular for use in an arrangement as claimed in claim 1, wherein:
the permanent magnetic assembly comprises at least one permanent magnetic unit (213) comprising a plurality of magnetic sub-elements (214),
the magnetic sub-elements (214) have individually fixed magnetization orientations, and
the magnetic sub-elements (214) are bonded together to form said at least one permanent magnetic unit (213).
